(19) United States
(12) Patent Application Publication
(10) Pub. No.: US 2026/0324405 A1
(43) Pub. Date: Oct. 15, 2026

(54) HYBRID DEVICE WITH BACKSIDE POWER DELIVERY NETWORKS AND ASSOCIATED SYSTEMS AND METHODS

(71) Applicant: Micron Technology, Inc., Boise, ID (US)

(72) Inventors: Nancy Lomeli, Boise, ID (US); Kyle K. Kirby, Eagle, ID (US); Michel Koopmans, Boise, ID (US)

(21) Appl. No.: 19/466,865

(22) Filed: Feb. 2, 2026

Related U.S. Application Data
(60) Provisional application No. 63/753,245, filed on Feb. 3, 2025.

(51) Int. Cl. H10W 20/41; H10B 80/00; H10D 80/30; H10D 84/01; H10D 84/85; H10W 90/00

(52) U.S. Cl. CPC H10W 20/435; H10B 80/00; H10D 80/30; H10D 84/0186; H10D 84/85; H10W 20/427; H10W 90/792

(57) ABSTRACT

Hybrid semiconductor devices with backside power delivery networks and associated systems and methods are disclosed herein. In some embodiments, a hybrid semiconductor device includes an array wafer, interconnect structures, a CMOS wafer, and a power delivery network. The interconnect structures can be disposed on the array wafer. The CMOS wafer can be bonded to array wafer. The power delivery network can include a backside power delivery (BPD) layer and an electrical connector. The BPD layer can be bonded to the CMOS wafer. The electrical connector can (i) extend from at least one of the interconnect structures and past the array and CMOS wafers in a first direction, and (ii) extend through the BPD layer in a second direction. The electrical connector can be operably coupled to the CMOS wafer and configured to deliver power thereto from the at least one of the interconnect structures.

### CROSS-REFERENCE TO RELATED APPLICATIONS

The present application claims priority to U.S. Provisional Patent Application No. 63/753,245, filed Feb. 3, 2025, the disclosure of which is incorporated herein by reference in its entirety.

### TECHNICAL FIELD

The present technology generally relates to hybrid semiconductor devices, and more particularly relates to hybrid semiconductor devices with backside power delivery networks and associated systems and methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIG. 1 is a schematic block diagram of a hybrid semiconductor device.

FIG. 2 is a schematic block diagram of a hybrid semiconductor device configured in accordance with embodiments of the present technology.

FIG. 3 is a schematic block diagram of another hybrid semiconductor device configured in accordance with embodiments of the present technology.

FIG. 4 is a schematic block diagram of yet another hybrid semiconductor device configured in accordance with embodiments of the present technology.

FIG. 5 is a flowchart illustrating a method for manufacturing a hybrid semiconductor device in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

Embodiments of the present technology are directed to hybrid semiconductor devices with backside power delivery networks and associated systems and methods. A hybrid semiconductor device can include multiple types of wafers, such as an array wafer (e.g., a NAND wafer, a DRAM wafer, and/or the like), a complementary metal-oxide-semiconductor (CMOS) wafer, and/or the like, that are stacked and bonded to one another. However, due to the stacked nature of the wafers, it may be challenging to effectively provide power to wafers that are further up in the stack and not directly coupled to interconnect structures.

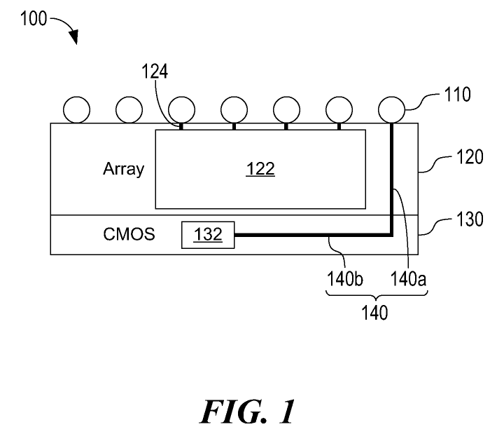

As an illustrative example, FIG. 1 is a schematic block diagram of a hybrid semiconductor device 100 (“the device 100”). The device 100 can include a plurality of interconnect structures 110, an array wafer 120, and a CMOS wafer 130. The plurality of interconnect structures 110 can be disposed on a frontside or backside of the array wafer 120, and the CMOS wafer 130 can be bonded to the other of the frontside or backside of the array wafer 120 in a F2F, B2F, B2B, or other suitable arrangement. The array wafer 120 can include integrated circuitry 122, and the CMOS wafer 130 can include integrated circuitry 132.

Power can be delivered to the device 100 from an external power source (not shown) operably coupled to the plurality of interconnect structures 110. As shown, the integrated circuitry 122 of the array wafer 120 can receive power directly from the plurality of interconnect structures 110 via one or more connectors 124 (e.g., bond wires). Because the plurality of interconnect structures 110 is disposed on one side of the array wafer 120, the one or more connectors 124 can extend directly (e.g., in straight lines) between the plurality of interconnect structures 110 and the integrated circuitry 122 of the array wafer 120. However, because the CMOS wafer 130 is bonded to the other side of the array wafer 120, it may be difficult to directly (e.g., in a straight line) connect the integrated circuitry 132 of the CMOS wafer 130 to the plurality of interconnect structures 110. For example, the integrated circuitry 122 of the array wafer 120 may serve as an obstacle that prevents forming a direct connection between the integrated circuitry 132 of the CMOS wafer 130 and the plurality of interconnect structures 110.

Therefore, a non-straight connection 140 may be formed to operably couple the integrated circuitry 132 of the CMOS wafer 130 to the plurality of interconnect structures 110. More specifically, (i) a first portion 140a of the connection 140 extends from one of the plurality of interconnect structures 110 and through the array wafer 120 in a first direction (e.g., in a vertical direction, in a direction substantially perpendicular to the first side of the array wafer 120), and (ii) a second portion 140b of the connection 140 extends from the first portion 140a to the integrated circuitry 132 of the CMOS wafer 130 in a second direction substantially perpendicular to the first direction (e.g., in a lateral direction, in a direction substantially parallel to the first side of the array wafer 120). Notably, the first portion 140a extends around (or away from) the integrated circuitry 122 of the array wafer 120. However, the second portion 140b extends laterally through a significant portion of the CMOS wafer 130, thereby occupying real estate in the CMOS wafer 130. Therefore, while the device 100 is able to deliver power to the integrated circuitry 132 of the CMOS wafer 130 without extending connections through the integrated circuitry 122 of the array wafer 120, it does so at the cost of rendering a significant portion of the CMOS wafer 130 unusable for, e.g., storing the integrated circuitry 132, among other components.

Embodiments of the present technology address at least some of the above described issues for providing both power to and sufficient space for integrated circuitry in CMOS wafers. For example, embodiments of the present disclosure include a power delivery network that provides power to a CMOS wafer while routing power connections external to the CMOS wafer, thereby avoiding taking up valuable real estate in the CMOS wafer. Thus, in some embodiments, a hybrid semiconductor device can include an array wafer, a plurality of interconnect structures, a CMOS wafer, and a power delivery network. Each of the array wafer and the CMOS wafer can include a first side and a second side opposite the first side. The plurality of interconnect structures can be disposed on the first side of the array wafer. The first side of the CMOS wafer can be bonded to the second side of the array wafer. The power delivery network can include a backside power delivery (BPD) layer and an electrical connector. The BPD layer can have a first side bonded to the second side of the CMOS wafer. The electrical connector can (i) extend from at least one of the plurality of interconnect structures and past the array wafer and the CMOS wafer in a first direction, and (ii) extend through the BPD layer in a second direction substantially perpendicular to the first direction. The electrical connector can be operably coupled to the CMOS wafer and configured to deliver power thereto from the at least one of the plurality of interconnect structures.

Embodiments of the present technology enable delivery of power to integrated circuitry in a CMOS wafer stacked on the opposite side of an array wafer as interconnect structures without using a significant portion of the space in the CMOS wafer itself. The BPD layer can provide space for power delivery routing external to the CMOS wafer. Also, as discussed in further detail herein, hybrid semiconductor devices configured in accordance with embodiments of the present technology can include additional wafers, and the BPD layer (and/or additional BPD layers) can be used to deliver power thereto without using significant portions of the space in such additional wafers. Accordingly, wafer space remains available for integrated circuitry, thereby saving costs and keeping the device compact. Moreover, the BPD layer can provide enhanced thermal management and support advanced thermal solutions, such as high thermal conductivity materials, microchannel cooling, phase change materials, thermal distribution networks (TDN), thermal vias, heat pipes, thermal siphons, or other thermal enhancing features either within the BPD layer or at the interface between the BPD layer and the CMOS. This modular design can provide better heat dissipation and thermal control, enhancing the scalability and reliability of high-density semiconductor devices.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

### II. Select Embodiments of Hybrid Semiconductor Devices

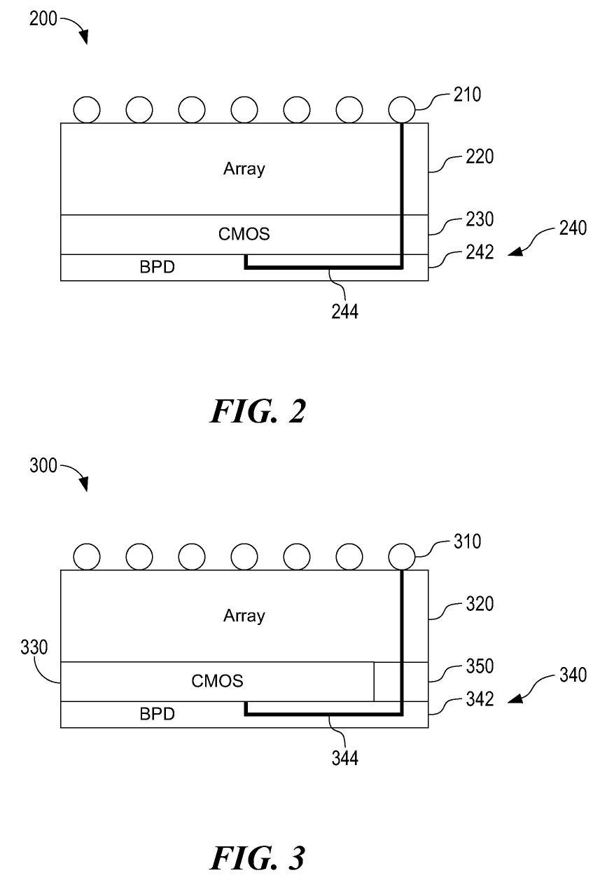

FIG. 2 is a schematic block diagram of a hybrid semiconductor device 200 (“the device 200”) configured in accordance with embodiments of the present technology. The device 200 can include a plurality of interconnect structures 210, an array wafer 220, a CMOS wafer 230, and a power delivery network 240. The plurality of interconnect structures 210 can include solder structures (e.g., solder balls), metal-metal bonds, hybrid bonds, and/or any other suitable conductive structure that mechanically and electrically couples the array wafer 120 to an external device (not shown; e.g., a power source). Each of the array wafer 220 and the CMOS wafer 230 can include a first side and a second side opposite the first side. The plurality of interconnect structures 210 can be disposed on the first side of the array wafer 220, and the first side of the CMOS wafer 230 can be bonded (e.g., via hybrid bonding) to the second side of the array wafer 220. For example, the CMOS wafer 230 can be bonded to the array wafer 220 in a F2F, B2F, B2B, or other suitable arrangement. In some embodiments, the array wafer 220 includes memory cells for storing data. For example, the array wafer 220 can be a NAND wafer. Alternatively, the array wafer 220 can be a DRAM wafer. The array wafer 220 can also include MRAM, PCM, and/or other memory structures. In some embodiments, the CMOS wafer 230 includes control logic, peripheral circuits, interface circuits, and/or the like for managing and controlling operation of the memory cells in the array wafer 220. In some embodiments, the array wafer 220 and/or the CMOS wafer 230 includes a reconstituted wafer formed from a plurality of known good dies (KGDs).

The power delivery network 240 can include a BPD layer 242 and an electrical connector 244. The BPD layer can include a first side and a second side opposite the first side, and the first side of the BPD layer can be bonded (e.g., via hybrid bonding) to the second side of the CMOS wafer 230. In some embodiments, the BPD layer 242 includes a low-k film having a dielectric constant less than 6, 5, 4, 3, 2, or 1. The electrical connector 244 can (i) extend from at least one of the plurality of interconnect structures 210 and past the array wafer 220 and the CMOS wafer 230 in a first direction (e.g., in a vertical direction, in a direction substantially perpendicular to the first side of the array wafer 220), and (ii) extend through the BPD layer 242 in a second direction substantially perpendicular to the first direction (e.g., in a lateral direction, in a direction substantially parallel to the first side of the array wafer 220). While the electrical connector 244 is illustrated as a singular component in FIG. 2, it is appreciated that the electrical connector 244 can include one or more separate and/or interconnected components (e.g., metal traces). In some embodiments, the electrical connector 244 includes a power rail formed via copper metallization. The electrical connector 244 can be operably coupled to the CMOS wafer 230 (e.g., to integrated circuitry thereof) and configured to deliver power thereto from the at least one of the plurality of interconnect structures. In some embodiments, portions of the electrical connector 244 extending through the BPD layer 242 are thicker and/or wider than portions of the electrical connector 244 extending through the array wafer 220 and/or the CMOS wafer 230.

As illustrated in FIG. 2, the electrical connector 244 extends only vertically through the CMOS wafer 230 (e.g., near the edge thereof) and does not extend laterally therethrough. Therefore, in some embodiments, the electrical connector 244 extends around an entirety of power-consuming components (not shown in FIG. 2; e.g., integrated circuitry) of the CMOS wafer 230. Also, because the electrical connector 244 extends laterally through the BPD layer 242, as opposed to through the CMOS wafer 230 (e.g., as depicted in FIG. 1), valuable real estate in the CMOS wafer 230 is not occupied by power routing, and instead remains available for integrated circuitry thereof. The BPD layer 242 can be relatively thin such that inclusion of the power delivery network 240 does not significantly increase the dimensions of the device 200.

FIG. 3 is a schematic block diagram of another hybrid semiconductor device 300 (“the device 300”) configured in accordance with embodiments of the present technology. The device 300 can be generally similar to the device 200 of FIG. 2. For example, the device 300 can include a plurality of interconnect structures 310, an array wafer 320, a CMOS wafer 330, and a power delivery network 340. The power delivery network 340 can include a BPD layer 342 and an electrical connector 344.

However, unlike the device 200, the device 300 additionally includes a dielectric spacer 350 disposed lateral to the CMOS wafer 330 and between the array wafer 320 and the BPD layer 342. More specifically, the CMOS wafer 330 has a smaller lateral dimension than each of the array wafer 320 and the BPD layer 342 such that the dielectric spacer 350 can be positioned in the gap created when the array wafer 320, the CMOS wafer 330, and the BPD layer 342 are stacked together. Therefore, the electrical connector 344 can extend through the dielectric spacer 350, but not through the CMOS wafer 330. The dielectric spacer 350 can provide mechanical support between the array wafer 320 and the BPD layer 342, and can also surround and protect the portion of the electrical connector 344 extending therethrough.

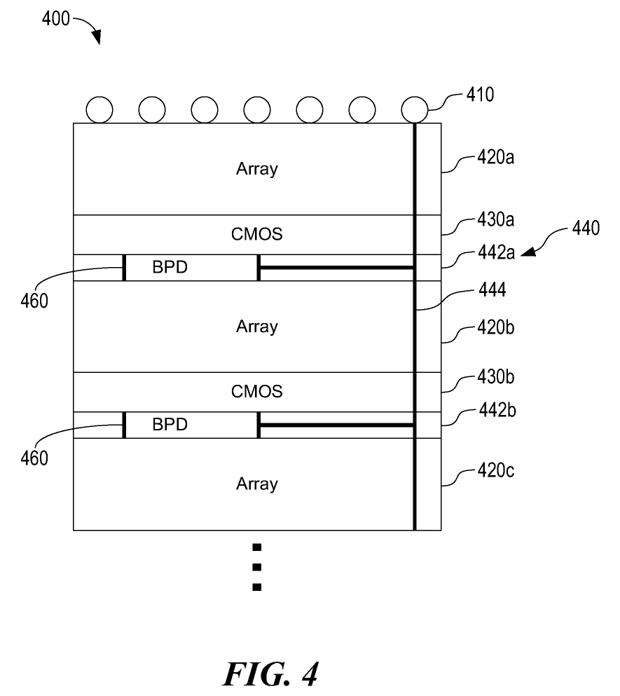

FIG. 4 is a schematic block diagram of yet another hybrid semiconductor device 400 (“the device 400”) configured in accordance with embodiments of the present technology. The device 400 can be generally similar to the device 200 of FIG. 2. For example, the device 400 can include a plurality of interconnect structures 410, an array wafer 420a, a CMOS wafer 430a, and a power delivery network 440. The power delivery network 440 can include a BPD layer 442a and an electrical connector 444.

However, unlike the device 200, the device 400 can additionally include one or more additional array wafers 420b, 420c, etc. and/or one or more additional CMOS wafers 430b, etc., and the power delivery network 440 can additionally include one or more additional BPD layers 442b, etc. Thus, the array wafers can be collectively referred to as “the plurality of array wafers 420,” the CMOS wafers can be collectively referred to as “the plurality of CMOS wafers 430,” and the BPD layers can be collectively referred to as “the plurality of BPD layers 442.” In the illustrated embodiment, the additional array wafer 420b is bonded to the BPD layer 442a, the additional CMOS wafer 430b is bonded to the additional array wafer 420b, the additional BPD layer 442b is bonded to the additional CMOS wafer 430b, and the additional array wafer 420c is bonded to the additional BPD layer 442b.

As shown, the electrical connector 444 can extend vertically through one or more of the plurality of array wafers 420, the plurality of CMOS wafers 430, and/or plurality of the BPD layers 442 and extend laterally through each of the BPD layers 442. In particular, the portion of the electrical connector 444 extending laterally through each of the BPD layers 442 can be operably and electrically coupled to the array wafer 420 and/or the CMOS wafer 430 stacked adjacent to the respective BPD layer 442. Therefore, each of the array wafers 420 and the CMOS wafers 430 can be operably coupled to receive power from the plurality of interconnect structures 410 without having the electrical connector 444 extend laterally through significant portions thereof, allowing memory cells, integrated circuits, and/or the like to occupy most of the space available therein.

In some embodiments, the device 400 further includes one or more wafer connectors 460 (e.g., TSVs) extending through a corresponding BPD layer 442 and between the array wafer 420 and the CMOS wafer 430 stacked adjacent to the corresponding BPD layer 442. The wafer connectors 460 can facilitate the transfer of power and/or data signals across the corresponding BPD layer 442 and between the array wafer 420 and the CMOS wafer 430. Notably, the wafer connectors 460 can be included in the device 400 in addition to or in place of select portions of the electrical connector 444.

In some embodiments, the array wafers 420, the CMOS wafers 430, and the BPD layers 442 can be manufactured separately. Thus, individual ones or select groups of the wafers and layers can be manufactured under unique and tailored conditions. For example, it may be desirable to manufacture the CMOS wafers 430 at relatively low temperatures and to manufacture the array wafers 420 at relatively high temperatures (e.g., for forming high quality oxides). In some embodiments, the array wafers 420, the CMOS wafers 430, and the BPD layers 442 can be manufactured together in-situ. For example, manufacturing the wafers and layers in a similar temperature regimen may be desirable for optimization.

It is appreciated that while FIG. 4 illustrates a certain number of the array wafers 420, the CMOS wafers 430, and the BPD layers 442 and in a particular arrangement, in other embodiments, a different number and/or a different arrangement of the array wafers 420, the CMOS wafers 430, and/or the BPD layers 442 can be included in the hybrid semiconductor device. Also, it is appreciated that while FIG. 4 illustrates the electrical connector 444 as a single unit, in other embodiments, the power delivery network 440 can include multiple electrical connectors. For example, a first electrical connector can operably couple the CMOS wafer 430a and the array wafer 420b to a first one of the plurality of interconnect structures 410, and a second electrical connector can operably couple the CMOS wafer 430b and the array wafer 420c to a second, different one of the plurality of interconnect structures 410.

### III. Select Embodiments of Methods for Manufacturing Hybrid Semiconductor Devices

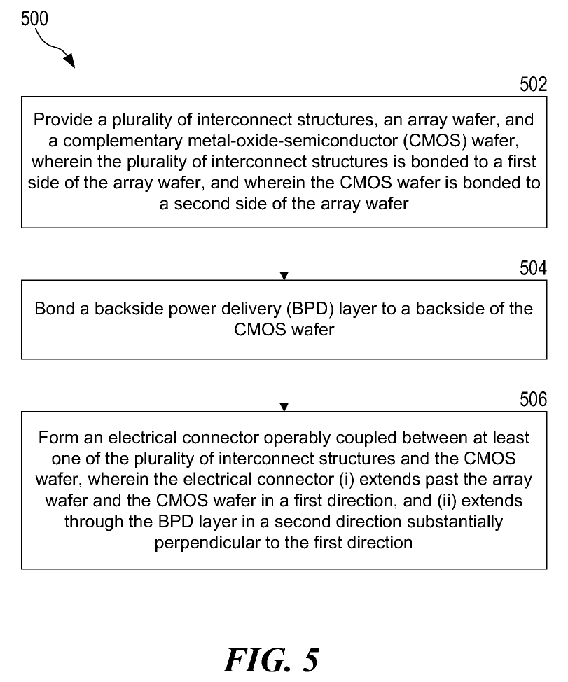

FIG. 5 is a flowchart illustrating a method 500 for manufacturing a hybrid semiconductor device in accordance with embodiments of the present technology. While the steps of the method 500 are described below in a particular order, one or more of the steps can be performed in a different order or omitted, and the method 500 can include additional and/or alternative steps. Additionally, although the method 500 may be described below with reference to the embodiments of the present technology described herein, the method 500 can be performed with other embodiments of the present technology.

The method 500 begins at block 502 by providing a plurality of interconnect structures, an array wafer, and a CMOS wafer. The plurality of interconnect structures can be disposed on a first side of the array wafer. The CMOS wafer can be bonded to a second side of the array wafer. In some embodiments, providing the plurality of interconnect structures, the array wafer, and the CMOS wafer comprises (i) processing each of the array wafer and the CMOS wafer separately, and (ii) bonding, after processing each of the array wafer and the CMOS wafer separately, the CMOS wafer to the array wafer. In some embodiments, providing the plurality of interconnect structures, the array wafer, and the CMOS wafer comprises (i) processing the array wafer, (ii) bonding, after processing the array wafer, the CMOS wafer to the array wafer, and (iii) processing, after bonding the CMOS wafer to the array wafer, the CMOS wafer.

At block 504, the method 500 continues by bonding a BPD layer to a second side of the CMOS wafer. In some embodiments, bonding the BPD layer comprises hybrid bonding the BPD layer to the second side of the CMOS wafer.

At block 506, the method 500 continues by forming an electrical connector operably coupled between at least one of the plurality of interconnect structures and the CMOS wafer. The electrical connector can (i) extend past the array wafer and the CMOS wafer in a first direction, and (ii) extend through the BPD layer in a second direction substantially perpendicular to the first direction. In some embodiments, forming the electrical connector comprises forming a power rail via copper metallization.

In some embodiments, the method 500 further continues by (i) bonding one or more additional array wafers to a second side of the BPD layer, and (ii) forming one or more through silicon vias (TSVs) extending through the BPD layer and between the CMOS wafer and at least one of the one or more additional array wafers. In some embodiments, the method 500 further continues by (i) bonding a second CMOS wafer to a second side of the BPD layer, (ii) bonding a second BPD layer to a second side of the second CMOS wafer, and (iii) extending the electrical connector past the second CMOS in the first direction and through the second BPD layer in the second direction to operably couple the at least one of the plurality of interconnect structures to the second CMOS wafer.

### IV. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. The terms “about” and/or “substantially” as used herein shall be interpreted to mean within ±10% of the stated value. Additionally, all ranges disclosed herein are to be understood to encompass the endpoints, and any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

What is claimed is:

1. A hybrid semiconductor device, comprising:
an array wafer having a first side and a second side opposite the first side;
a plurality of interconnect structures disposed on the first side of the array wafer;
a complementary metal-oxide-semiconductor (CMOS) wafer having a first side and a second side opposite the first side, wherein the first side of the CMOS wafer is bonded to the second side of the array wafer; and
a power delivery network including:
a backside power delivery (BPD) layer having a first side bonded to the second side of the CMOS wafer, and
an electrical connector (i) extending from at least one of the plurality of interconnect structures and past the array wafer and the CMOS wafer in a first direction, and (ii) extending through the BPD layer in a second direction substantially perpendicular to the first direction,
wherein the electrical connector is operably coupled to the CMOS wafer and configured to deliver power thereto from the at least one of the plurality of interconnect structures.

2. The hybrid semiconductor device of claim 1, wherein the BPD layer includes a low-k film having a dielectric constant less than 3.

3. The hybrid semiconductor device of claim 1, wherein the electrical connector includes a power rail formed via copper metallization.

4. The hybrid semiconductor device of claim 1, wherein the plurality of interconnect structures includes hybrid bonds, wherein the first side of the CMOS wafer is hybrid bonded to the second side of the array wafer, and wherein the first side of the BPD layer is hybrid bonded to the second side of the CMOS wafer.

5. The hybrid semiconductor device of claim 1, wherein the electrical connector extends around an entirety of power-consuming components of the CMOS wafer.

6. The hybrid semiconductor device of claim 1, further comprising one or more additional array wafers bonded to a second side of the BPD layer, wherein the electrical connector is operably coupled to each of the one or more additional array wafers and configured to deliver power thereto from the at least one of the plurality of interconnect structures.

7. The hybrid semiconductor device of claim 1, further comprising:
one or more additional array wafers bonded to a second side of the BPD layer; and
one or more through silicon vias (TSVs) extending through the BPD layer and between the CMOS wafer and at least one of the one or more additional array wafers.

8. The hybrid semiconductor device of claim 1, further comprising a second CMOS wafer, wherein a first side of the second CMOS wafer is bonded to a second side of the BPD layer, wherein the power delivery network further includes a second BPD layer, wherein a first side of the second BPD layer is bonded to a second side of the second CMOS wafer, wherein the electrical connector (i) extends past the second CMOS wafer in the first direction and (ii) extends through the second BPD layer in the second direction, and wherein the electrical connector is operably coupled to the second CMOS wafer and configured to deliver power thereto from the at least one of the plurality of interconnect structures.

9. The hybrid semiconductor device of claim 1, wherein the electrical connector extends through each of the array wafer and the CMOS wafer in the first direction.

10. The hybrid semiconductor device of claim 1, further comprising a dielectric spacer disposed lateral to the CMOS wafer and between the array wafer and the BPD layer, wherein the electrical connector extends through the dielectric spacer and does not extend through the CMOS wafer.

11. The hybrid semiconductor device of claim 1, wherein at least one of the array wafer or the CMOS wafer includes a reconstituted wafer formed from a plurality of known good dies (KGDs).

12. The hybrid semiconductor device of claim 1, wherein the array wafer includes a NAND wafer or a DRAM wafer.

13. The hybrid semiconductor device of claim 1, wherein the BPD layer includes one or more of a cooling microchannels, a thermal distribution network (TDN), a thermal via, a heat pipe, and a thermal siphon.

14. A method for manufacturing a hybrid semiconductor device, the method comprising:
providing a plurality of interconnect structures, an array wafer, and a complementary metal-oxide-semiconductor (CMOS) wafer, wherein the plurality of interconnect structures is disposed on a first side of the array wafer, and wherein the CMOS wafer is bonded to a second side of the array wafer;
bonding a backside power delivery (BPD) layer to a second side of the CMOS wafer; and
forming an electrical connector operably coupled between at least one of the plurality of interconnect structures and the CMOS wafer, wherein the electrical connector (i) extends past the array wafer and the CMOS wafer in a first direction, and (ii) extends through the BPD layer in a second direction substantially perpendicular to the first direction.

15. The method of claim 14, wherein providing the plurality of interconnect structures, the array wafer, and the CMOS wafer comprise:
processing each of the array wafer and the CMOS wafer separately; and
bonding, after processing each of the array wafer and the CMOS wafer separately, the CMOS wafer to the array wafer.

16. The method of claim 14, wherein providing the plurality of interconnect structures, the array wafer, and the CMOS wafer comprises:
processing the array wafer;
bonding, after processing the array wafer, the CMOS wafer to the array wafer; and
processing, after bonding the CMOS wafer to the array wafer, the CMOS wafer.

17. The method of claim 14, wherein forming the electrical connector comprises forming a power rail via copper metallization.

18. The method of claim 14, wherein bonding the BPD layer comprises hybrid bonding the BPD layer to the second side of the CMOS wafer.

19. The method of claim 14, further comprising delivering power to the CMOS wafer via the at least one of the plurality of interconnect structures and the electrical connector.

20. The method of claim 14, further comprising:
bonding one or more additional array wafers to a second side of the BPD layer; and
forming one or more through silicon vias (TSVs) extending through the BPD layer and between the CMOS wafer and at least one of the one or more additional array wafers.

21. The method of claim 14, further comprising:
bonding a second CMOS wafer to a second side of the BPD layer;
bonding a second BPD layer to a second side of the second CMOS wafer; and
extending the electrical connector past the second CMOS in the first direction and through the second BPD layer in the second direction to operably couple the at least one of the plurality of interconnect structures to the second CMOS wafer.
